(19) United States
(12) Patent Application Publication
(10) Pub. No.: US 2025/0093425 A1
(43) Pub. Date: Mar. 20, 2025

(54) BATTERY PACK DIAGNOSIS APPARATUS AND METHOD

(71) Applicant: SAMSUNG SDI CO., LTD., Yongin-si (KR)

(72) Inventor: Min Su KIM, Suwon-si (KR)

(21) Appl. No.: 18/765,496

(22) Filed: Jul. 8, 2024

(30) Foreign Application Priority Data
Sep. 20, 2023 (KR) 10-2023-0125452

(51) Int. Cl. G01R 31/392; B60L 58/16; G01R 31/36; G01R 31/367; G01R 31/385

(52) U.S. Cl. CPC G01R 31/392; B60L 58/16; G01R 31/3646; G01R 31/367; G01R 31/385

(57) ABSTRACT

A battery pack diagnosis apparatus includes a sensor module which detects noise and a processor which extracts noise generated in the battery pack from the noise detected by the sensor module, analyzes the noise generated in the battery pack, and diagnoses a state of a battery pack. A battery pack diagnosis method includes detecting, by a sensor module, noise, extracting, by a processor, noise generated in a battery pack from the noise detected by the sensor module and analyzing, by the processor, the noise generated in the battery pack to diagnose a state of the battery pack.

### CROSS-REFERENCE TO RELATED APPLICATION

This application claims priority to and the benefit of Korean Patent Application No. 10-2023-0125452, filed on Sep. 20, 2023, the disclosure of which is incorporated herein by reference in its entirety.

### BACKGROUND

### 1. Field

Embodiments of the present disclosure relate to a battery pack diagnosis apparatus and method.

### 2. Description of the Related Art

Electric vehicles have many advantages in terms of the environment and maintenance but have many problems in the stability of battery packs. For example, busbar vibrations in a battery pack due to a busbar fixing error, a bolt rolling in the battery pack due to a bolt assembly error, abnormal operation of a high voltage relay, enclosure cover being melted by heating or ignition of circuit components, and the like can be potential safety hazards for users.

Accordingly, a method in which a battery management system analyzes a state of a battery after monitoring data of a voltage, a current, and a temperature of the battery, or analyzes an internal structure of a battery pack using X-ray technology has been disclosed.

However, the method of analyzing the battery pack has a limitation in detecting and analyzing intermittent problems occurring in the battery pack in real time.

### SUMMARY

Embodiments include a battery pack diagnosis apparatus. The apparatus includes a sensor module which detects noise and a processor which extracts noise generated in the battery pack from the noise detected by the sensor module, analyzes the noise generated in the battery pack, and diagnoses a state of a battery pack.

The sensor module may include a first sensor installed outside the battery pack to detect noise and a second sensor installed in the battery pack to detect noise.

The first sensor may include a microphone assembly designed to be omnidirectional to detect noise in multiple directions.

The second sensor may include a microphone assembly which is designed to be unidirectional or to have a cardioid pattern to detect noise generated in the battery pack.

The processor may extract noise generated in the battery pack by comparing a sound volume of the noise detected by the first sensor with a sound volume of the noise detected by the second sensor according to whether the noise detected by the first sensor and the noise detected by the second sensor are the same.

If the sound volume of the noise detected by the first sensor is greater than the sound volume of the noise detected by the second sensor, the processor may determine that the noise detected by the first sensor and the second sensor is noise generated outside the battery pack and may remove the noise.

The processor may diagnose the state of the battery pack on the basis of a frequency pattern of the noise generated in the battery pack.

The processor may diagnose an abnormal phenomenon of the battery pack by comparing the frequency pattern of the noise generated in the battery pack with each set pattern set for abnormal phenomena of the battery pack.

The processor may store set patterns for each travel state of a vehicle and may diagnose the abnormal phenomenon of the battery pack according to the travel state of the vehicle.

Embodiments include a battery pack diagnosis method. The method includes detecting, by a sensor module, noise, extracting, by a processor, noise generated in a battery pack from the noise detected by the sensor module and analyzing, by the processor, the noise generated in the battery pack to diagnose a state of the battery pack.

The sensor module may include a first sensor installed outside the battery pack to detect noise and a second sensor installed in the battery pack to detect noise.

The first sensor may include a microphone assembly designed to be omnidirectional to detect noise in multiple directions.

The second sensor may include a microphone assembly which is designed to be unidirectional or to have a cardioid pattern to detect the noise generated in the battery pack.

In extracting the noise generated in the battery pack from the noise detected by the sensor module, the processor may extract the noise generated in the battery pack by comparing a sound volume of the noise detected by the first sensor with a sound volume of the noise detected by the second sensor according to whether the noise detected by the first sensor and the noise detected by the second sensor are the same.

In extracting the noise generated in the battery pack from the noise detected by the sensor module, if the sound volume of the noise detected by the first sensor is greater than the sound volume of the noise detected by the second sensor, the processor may determine that the noise detected by the first sensor and the second sensor is noise generated outside the battery pack and may remove the noise.

In analyzing the noise generated in the battery pack to diagnose the state of the battery pack, the processor may diagnose the state of the battery pack on the basis of a frequency pattern of the noise generated in the battery pack.

In analyzing the noise generated in the battery pack to diagnose the state of the battery pack, the processor may diagnose an abnormal phenomenon of the battery pack by comparing the frequency pattern of the noise generated in the battery pack with each set pattern set for abnormal phenomena of the battery pack.

In analyzing the noise generated in the battery pack to diagnose the state of the battery pack, the processor may store set patterns for each travel state of a vehicle and may diagnose the abnormal phenomenon of the battery pack according to the travel state of the vehicle.

### BRIEF DESCRIPTION OF THE DRAWINGS

Features will become apparent to those of skill in the art by describing in detail exemplary embodiments with reference to the attached drawings in which:

FIG. 1 is a view illustrating a battery pack diagnosis apparatus;

FIG. 2 is a view illustrating installation locations of a first sensor and a second sensor;

FIG. 3 is a view illustrating a learning processor of a machine learning model; and

FIG. 4 is a flowchart illustrating a battery pack diagnosis method.

### DETAILED DESCRIPTION

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain embodiments in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will also be understood that, although the terms first, second, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

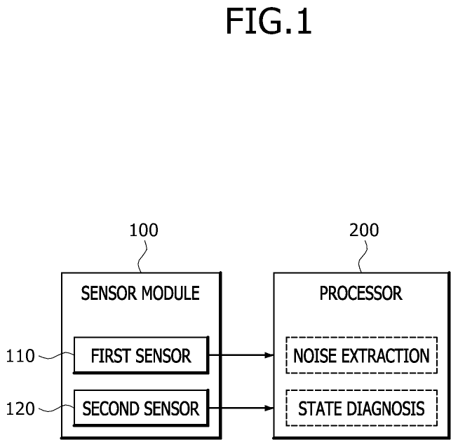

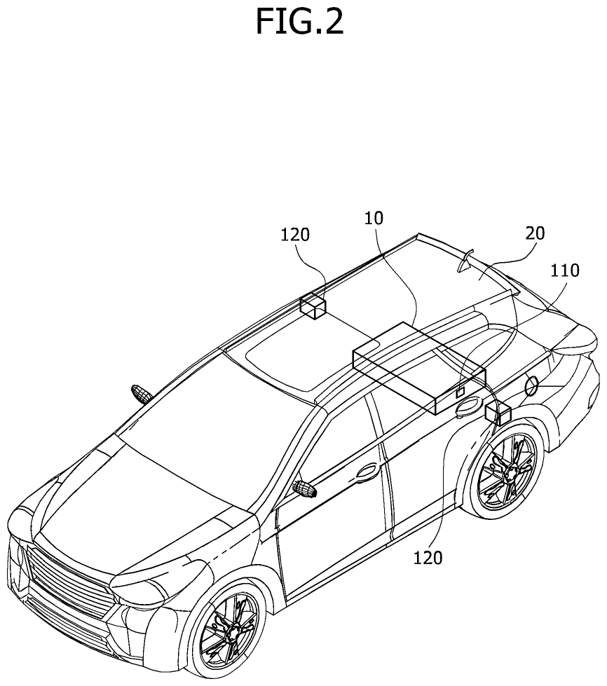

FIG. 1 is a view illustrating a battery pack diagnosis apparatus, and FIG. 2 is a view illustrating installation locations of a first sensor and a second sensor.

Referring to FIG. 1, the battery pack diagnosis apparatus according to one or more embodiments may include a sensor module 100 and a processor 200.

The sensor module 100 may detect noise generated outside the battery pack 10 or noise generated in the battery pack 10.

The battery pack 10 may include at least one battery module and a pack housing provided with an accommodation space for accommodating the battery module(s).

The battery module may include a plurality of battery cells and a module housing.

The battery cells in a stack type may be accommodated in the module housing. The battery cell may include a positive electrode lead and a negative electrode lead. In one or more embodiments, the battery cell may be used in a cylindrical type, prismatic type, or pouch type according to the types of batteries.

One cell stack instead of the battery module may constitute one module in the battery pack 10. The cell stack may be accommodated in the accommodation space of the pack housing or an accommodation space partitioned by a frame or partition.

The battery cell generates a large amount of heat during charging/discharging. The generated heat is accumulated in the battery cell and accelerates the degradation of the battery cell. Accordingly, the battery pack 10 may further include a cooling member to suppress the degradation of the battery cell. In some embodiments, the cooling member may be provided under the accommodation space in which the battery cell is accommodated, but in other embodiments may be provided at a side of or above the accommodation space according to the battery pack 10.

Exhaust gas inside the battery cell generated under abnormal operation conditions known as a thermal runaway or thermal event may be discharged to the outside of the battery cell. The battery pack 10 or the battery module may include an exhaust port or the like for discharging the exhaust gas to prevent the exhaust gas from damaging the battery pack 10 or the module.

The battery pack 10 may include a battery and a battery management system (BMS) for managing the battery. The BMS may include a detecting unit, a balancing unit, and a control unit. The battery module may include a plurality of cells (e.g., battery cells) connected in series or parallel. The battery modules may be connected in series or parallel.

The sensor module 100 may include a first sensor 110 and a second sensor 120.

Referring to FIG. 2, the first sensor 110 may be installed outside the battery pack 10 to detect noise.

The first sensor 110 may be installed at any of various locations on a vehicle body. As the first sensor 110 may be installed on the vehicle body, the first sensor 110 may be more advantageous for detecting noise generated outside a vehicle 20 when compared to the second sensor 120. The installation location and structure of the second sensor 120 will be described below.

The first sensor 110 may be installed in an anti-dust waterproof case according to an installation location and may be protected using a shock-absorbing material. The installation structure and method of the first sensor 110 can take various forms.

In one or more embodiments, the first sensor 110 may be designed to be omnidirectional and may be a micro-electromechanical systems (MEMS) microphone assembly that detects noise in a plurality of directions, but may be of various types. If the first sensor 110 is designed to be omnidirectional, the first sensor 110 can detect noise generated in the plurality of directions.

Referring to FIG. 2, the second sensor 120 may be installed in the battery pack 10 to detect noise.

The second sensor 120 may be installed in the battery pack 10 or the housing of the battery pack 10, but the installation location of the second sensor 120 can be varied. If the second sensor 120 is installed in the battery pack 10 or the housing of the battery pack 10, the second sensor 120 may be more advantageous for detecting noise generated in the battery pack 10 when compared to the first sensor 110.

The second sensor 120 may be located in a case formed of a heatproof material which may withstand high temperatures, vibrations, and the like according to the installation location.

The second sensor 120 may be designed to be unidirectional or to have a cardioid pattern and may be a MEMS microphone assembly that detects noise in a specific direction, but a type thereof can be varied.

If the second sensor 120 is designed to be unidirectional or to have the cardioid pattern, the second sensor 120 may more effectively detect noise generated in the battery pack 10 when compared to the first sensor 110.

The processor 200 may extract noise generated in the battery pack 10 from noise detected by the sensor module 100 and may analyze the noise generated in the battery pack 10 to diagnose a state of the battery pack 10.

In embodiments, the processor 200 may receive noise detected by the first sensor 110 and noise detected by the second sensor 120 and may store the noise in a memory (not shown) such as a cache or other memory.

The processor 200 may extract noise generated in the battery pack 10 by comparing a sound volume of the noise detected by the first sensor 110 with a sound volume of the noise detected by the second sensor 120 according to whether the noise detected by the first sensor 110 and the noise detected by the second sensor 120 are the same, e.g., substantially the same.

In one or more embodiments, the processor 200 may extract a frequency pattern of the noise detected by the first sensor 110.

The processor 200 may extract a frequency pattern of the noise detected by the second sensor 120.

The processor 200 may determine whether the frequency pattern of the noise detected by the first sensor 110 and the frequency pattern of the noise detected by the second sensor 120 are the same by comparing the frequency pattern of the noise detected by the first sensor 110 with the frequency pattern of the noise detected by the second sensor 120.

If the frequency pattern of the noise detected by the first sensor 110 and the frequency pattern of the noise detected by the second sensor 120 are the same, the processor 200 may determine that the noise detected by the first sensor 110 and the noise detected by the second sensor 120 are the same.

When it is determined that the noise detected by the first sensor 110 and the noise detected by the second sensor 120 are the same, e.g., substantially the same, the processor 200 may extract a sound volume of the noise detected by the first sensor 110 and a sound volume of the noise detected by the second sensor 120.

The processor 200 may compare the sound volume of the noise detected by the first sensor 110 with the sound volume of the noise detected by the second sensor 120.

If the sound volume of the noise detected by the first sensor 110 is greater than the sound volume of the noise detected by the second sensor 120, the processor 200 may determine that the noise detected by the first sensor 110 and the second sensor 120 is noise generated outside the vehicle 20.

The processor 200 may prevent a diagnosis error for the battery pack 10 by removing the noise generated outside the vehicle 20 from the noise detected by the second sensor 120.

If the sound volume of the noise detected by the second sensor 120 is greater than the sound volume of the noise detected by the first sensor 110, the processor 200 may determine that the noise detected by the first sensor 110 and the second sensor 120 is noise generated in the battery pack 10.

In addition, when noise is not detected by the first sensor 110 and is detected only by the second sensor 120, the processor 200 may determine that the noise detected by the second sensor 120 is noise generated in the battery pack 10.

The processor 200 may compare a frequency pattern of the noise generated in the battery pack 10 with a predetermined set pattern and diagnose an abnormal phenomenon of the battery pack 10 according to a comparison result.

A set pattern may be set for each abnormal phenomenon of the battery pack 10. Various types of noise for each abnormal phenomenon, such as busbar vibrations, a bolt assembly error, an abnormal operation of a high voltage relay, or heating of a circuit component in the battery pack 10, may occur. Accordingly, in one or more embodiments, a set pattern may be set for each of the busbar vibrations, the bolt assembly error, the abnormal operation of a high voltage relay, and the heating of the circuit component in the battery pack 10.

In embodiments, the set patterns may be variously set according to a travel state of the vehicle. The travel state of the vehicle may be at least one of a vehicle stopped state, a vehicle traveling state, and a vehicle engine-off state. The processor 200 may diagnose an abnormal phenomenon of the battery pack 10 for each travel state of the vehicle.

Accordingly, the processor 200 may diagnose an abnormal phenomenon of the battery pack 10 after learning frequency patterns of noise generated due to abnormal phenomena of the battery pack 10, such as busbar vibrations, a bolt assembly error, an abnormal operation of a high voltage relay, and heating of a circuit component through a machine learning technique, and analyzing noise generated in the battery pack 10 through the machine learning technique.

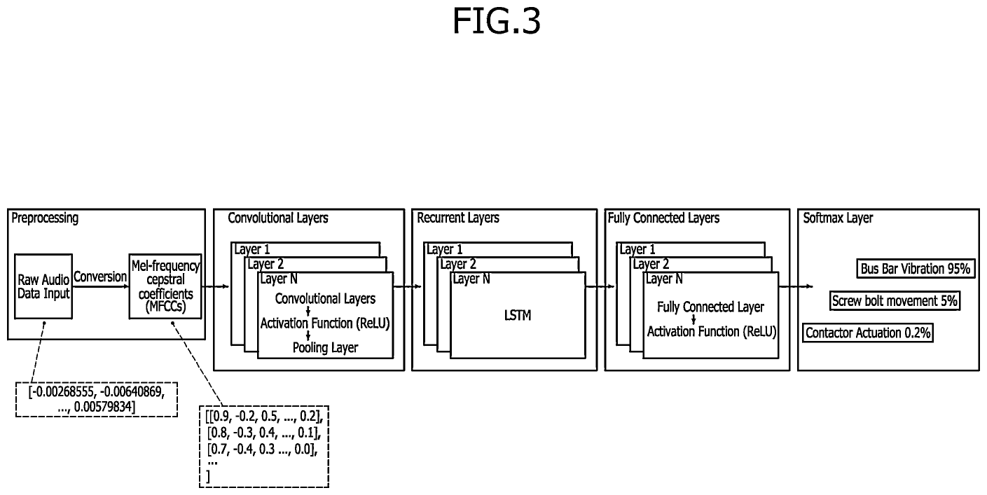

FIG. 3 is a view illustrating a learning processor of a machine learning model.

Referring to FIG. 3, the processor 200 may preprocess sound data in a raw waveform. In embodiments, the processor 200 may convert the sound data into the form of mel-frequency cepstral coefficients (MFCCs) spectrograms or mel-spectrograms to be used as two-dimensional (2D) data.

MFCCs may be formed by a method of imitating a person's auditory system. The MFCC may obtain 2D data by converting an audio spectrum into a maker frequency first, log-transforming the converted spectrum, and performing a discrete cosine conversion on the log-transformed spectrum. As a result, the MFCC may be expressed as a multidimensional vector.

Convolutional layers may process 2D data and learn a local pattern in the sound data. Generally, the convolutional layers may include several convolution layers and pulling layers, and a dimension of the sound data may be decreased and important information may be emphasized through the convolutional layers. The convolutional layers transform an output thereof into sequence data and the sequence data may be input to recurrent layers.

The output of the convolutional layers may be converted into the sequence data and transmitted to the recurrent layers.

The recurrent layers may provide useful information for learning a frequency pattern over time.

Fully connected layers may perform final classification by combining information extracted by the recurrent layers. A softmax activation function may be used in the fully connected layers, and probability may be output as a result.

A softmax layer outputs a probability for each class. In this example embodiment, a class having the highest probability may be selected as an estimated result.

In order to learn a pattern of the sound data, a machine learning (ML) model process may be configured with a convolutional recurrent neural network structure (CRNN) in which a convolutional neural network (CNN) and a recurrent neural network (RNN) are combined. Such a network operates for 2D data and sequence data such as an image. Sound data may correspond to the 2D data and the sequence data.

As described above, learning may be performed on the frequency pattern, the processor 200 may compare a frequency pattern of noise generated in the battery pack 10 with a set pattern through a machine learning technique and diagnose an abnormal phenomenon of the battery pack 10 according to a comparison result. In embodiments, the processor 200 may compare the frequency pattern with the set pattern to extract the abnormal phenomenon with the highest probability according to a similarity therebetween. In one or more embodiments, the processor 200 may determine that an abnormal phenomenon of the battery pack 10 is at least one of busbar vibrations, a bolt assembly error, an abnormal operation of a high voltage relay, and heating of a circuit component of the battery pack 10.

The processor 200 may be connected to a memory (not shown) and execute commands stored in the memory. The processor may execute the commands stored in the memory to control at least another component (for example, a hardware or software component) connected to the processor and perform processing or calculating on various types of data.

In addition, the processor 200 may be formed to be divided in a hardware, software, or logic level to perform each function. In an example embodiment, dedicated hardware for performing each function may be used. To this end, the processor may be implemented as or include at least one of an application specific integrated circuit (ASIC), a digital signal processor (DSP), a programmable logic device (PLD), field programmable gate arrays (FPGAs), a central processing unit (CPU), microcontrollers and/or microprocessors.

In embodiments, the processor 200 may be implemented as a CPU or system on chip (SoC), may drive an operating system or application to control a plurality of hardware or software components connected to the processor, and may perform processing and calculating on various types of data. The processor may be configured to execute at least one command stored in a memory and may store execution result data in the memory.

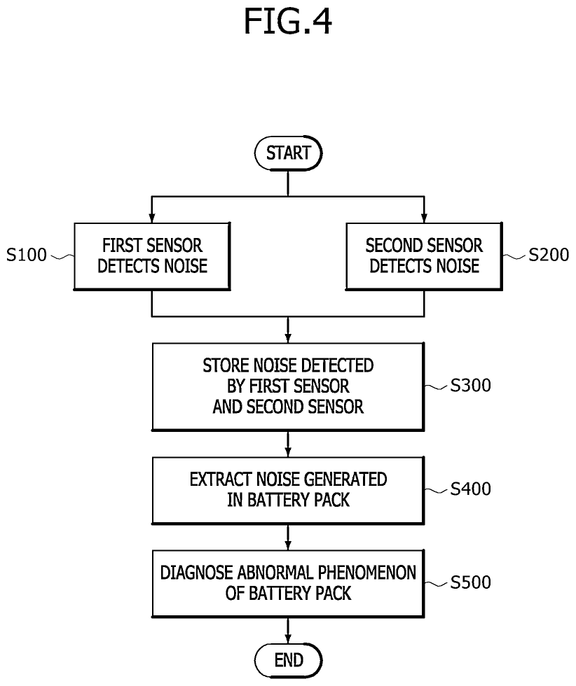

Hereinafter, a battery pack diagnosis method according to one or more embodiments will be described with reference FIG. 4.

FIG. 4 is a flowchart illustrating an embodiment of a battery pack diagnosis method.

Referring to FIG. 4, the first sensor 110 may detect noise generated outside the vehicle 20 or noise generated in the battery pack 10 (S100).

The second sensor 120 may detect noise generated outside the vehicle 20 or noise generated in the battery pack 10 (S200).

The processor 200 may store the noise detected by the first sensor 110 and the noise detected by the second sensor 120 (S300).

The processor 200 may extract noise generated in the battery pack 10 by removing the noise generated outside the vehicle 20 from the noise detected by the second sensor 120 (S400).

To this end, the processor 200 may extract a frequency pattern of the noise detected by the first sensor 110 and a frequency pattern of the noise detected by the second sensor 120.

The processor 200 may determine whether the frequency pattern of the noise detected by the first sensor 110 and the frequency pattern of the noise detected by the second sensor 120 are the same by comparing the frequency pattern of the noise detected by the first sensor 110 with the frequency pattern of the noise detected by the second sensor 120.

If the frequency pattern of the noise detected by the first sensor 110 and the frequency pattern of the noise detected by the second sensor 120 are the same, the processor 200 may determine that the noise detected by the first sensor 110 and the noise detected by the second sensor 120 are the same.

If it is determined that the noise detected by the first sensor 110 and the noise detected by the second sensor 120 are the same, the processor 200 may extract a sound volume of the noise detected by the first sensor 110 and a sound volume of the noise detected by the second sensor 120. The processor 200 may compare the sound volume of the noise detected by the first sensor 110 with the sound volume of the noise detected by the second sensor 120. As a comparison result, when the sound volume of the noise detected by the first sensor 110 is greater than the sound volume of the noise detected by the second sensor 120, the processor 200 may determine that the noise detected by the first sensor 110 and the second sensor 120 are noise generated outside the vehicle 20.

The processor 200 may then remove the noise generated outside the vehicle 20 from the noise detected by the second sensor 120.

If the sound volume of the noise detected by the second sensor 120 is greater than the sound volume of the noise detected by the first sensor 110, the processor 200 may determine that the noise detected by the first sensor 110 and the second sensor 120 is noise generated in the battery pack 10.

As the noise generated in the battery pack 10 may be extracted, the processor 200 may compare a frequency pattern of the noise generated in the battery pack 10 with a set pattern through a machining learning technique and diagnose an abnormal phenomenon of battery pack 10 according to a comparison result (S500). In an example embodiment, the processor 200 may compare the frequency pattern with the set pattern and extract the abnormal phenomenon with the highest probability according to a similarity therebetween.

As described above, in one or more embodiments, noise generated in the battery pack 10 may be analyzed to quickly and accurately diagnose the battery pack 10.

In addition, in one or more embodiments of the present disclosure, a maintenance cost of the battery pack 10 may be reduced, a failure of the battery pack 10 may be prevented, and safety of a user may be ensured.

The present disclosure is directed to providing a battery pack diagnosis apparatus and method for quickly and accurately diagnosing a battery pack by analyzing noise generated in a battery pack.

According to embodiments of the present disclosure, there is provided a battery pack diagnosis apparatus which extracts noise generated in a battery pack and diagnoses a state of the battery pack through a machine learning technique.

The embodiments described in this specification can be implemented through, for example, a method, a process, an apparatus, a software program, a data stream, or a signal. Even when embodiments of the present disclosure are described as being implemented in only a single form (for example, as a method), the described features may be implemented in another form (for example, as an apparatus or program). The apparatus may be implemented using hardware, software, firmware, or the like. The method may be implemented in, for example, an apparatus such as a processor which generally refers to a processing device such as a computer, a microprocessor, an integrated circuit, and a programmable logic device. The processor also includes a communication device such as a computer, and other devices which facilitate information communication between end-users.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A battery pack diagnosis apparatus, comprising:
a sensor module which detects noise; and
a processor which extracts noise generated in the battery pack from the noise detected by the sensor module, analyzes the noise generated in the battery pack, and diagnoses a state of a battery pack.

2. The battery pack diagnosis apparatus as claimed in claim 1, wherein the sensor module includes:
a first sensor installed outside the battery pack to detect noise; and
a second sensor installed in the battery pack to detect noise.

3. The battery pack diagnosis apparatus as claimed in 2, wherein the first sensor includes a microphone assembly designed to be omnidirectional to detect noise in a plurality of directions.

4. The battery pack diagnosis apparatus as claimed in 2, wherein the second sensor includes a microphone assembly which is designed to be unidirectional or to have a cardioid pattern to detect noise generated in the battery pack.

5. The battery pack diagnosis apparatus as claimed in 2, wherein the processor extracts noise generated in the battery pack by comparing a sound volume of the noise detected by the first sensor with a sound volume of the noise detected by the second sensor according to whether the noise detected by the first sensor and the noise detected by the second sensor are the same.

6. The battery pack diagnosis apparatus as claimed in 5, wherein, when the sound volume of the noise detected by the first sensor is greater than the sound volume of the noise detected by the second sensor, the processor determines that the noise detected by the first sensor and the second sensor is noise generated outside the battery pack and removes the noise.

7. The battery pack diagnosis apparatus as claimed in 1, wherein the processor diagnoses the state of the battery pack on the basis of a frequency pattern of the noise generated in the battery pack.

8. The battery pack diagnosis apparatus as claimed in 7, wherein the processor diagnoses an abnormal phenomenon of the battery pack by comparing the frequency pattern of the noise generated in the battery pack with each set pattern set for abnormal phenomena of the battery pack.

9. The battery pack diagnosis apparatus as claimed in 8, wherein the processor stores set patterns for each travel state of a vehicle and diagnoses the abnormal phenomenon of the battery pack according to the travel state of the vehicle.

10. A battery pack diagnosis method, comprising:
detecting, by a sensor module, noise;
extracting, by a processor, noise generated in a battery pack from the noise detected by the sensor module; and
analyzing, by the processor, the noise generated in the battery pack to diagnose a state of the battery pack.

11. The method as claimed in 10, wherein the sensor module includes:
a first sensor installed outside the battery pack to detect noise; and
a second sensor installed in the battery pack to detect noise.

12. The method as claimed in 11, wherein the first sensor includes a microphone assembly designed to be omnidirectional to detect noise in a plurality of directions.

13. The method as claimed in 11, wherein the second sensor includes a microphone assembly which is designed to be unidirectional or to have a cardioid pattern to detect the noise generated in the battery pack.

14. The method as claimed in 11, wherein, in the extracting of the noise generated in the battery pack from the noise detected by the sensor module, the processor extracts the noise generated in the battery pack by comparing a sound volume of the noise detected by the first sensor with a sound volume of the noise detected by the second sensor according to whether the noise detected by the first sensor and the noise detected by the second sensor are the same.

15. The method as claimed in 14, wherein, in the extracting of the noise generated in the battery pack from the noise detected by the sensor module, when the sound volume of the noise detected by the first sensor is greater than the sound volume of the noise detected by the second sensor, the processor determines that the noise detected by the first sensor and the second sensor is noise generated outside the battery pack and removes the noise.

16. The method as claimed in 10, wherein, in the analyzing of the noise generated in the battery pack to diagnose the state of the battery pack, the processor diagnoses the state of the battery pack on the basis of a frequency pattern of the noise generated in the battery pack.

17. The method as claimed in 16, wherein, in the analyzing of the noise generated in the battery pack to diagnose the state of the battery pack, the processor diagnoses an abnormal phenomenon of the battery pack by comparing the frequency pattern of the noise generated in the battery pack with each set pattern set for abnormal phenomena of the battery pack.

18. The method as claimed in 17, wherein, in the analyzing of the noise generated in the battery pack to diagnose the state of the battery pack, the processor stores set patterns for each travel state of a vehicle and diagnoses the abnormal phenomenon of the battery pack according to the travel state of the vehicle.
